(19) United States
(12) Patent Application Publication
(10) Pub. No.: US 2024/0298554 A1
(43) Pub. Date: Sep. 5, 2024

(54) SWICH BASED ON A PHASE-CHANGE MATERIAL

(71) Applicant: Commissariat à l'Énergie Atomique et aux Énergies Alternatives, Paris (FR)

(72) Inventors: Denis Mercier, Grenoble Cedex 9 (FR); Bruno Reig, Grenoble Cedex 9 (FR)

(73) Assignee: Commissariat à l'Énergie Atomique et aux Énergies Alternatives, Paris (FR)

(21) Appl. No.: 18/591,120

(22) Filed: Feb. 29, 2024

(30) Foreign Application Priority Data
Mar. 3, 2023 (FR) 2302012

(51) Int. Cl. H10N 70/00; H10N 70/20

(52) U.S. Cl. CPC H10N 70/8413; H10N 70/231; H10N 70/823; H10N 70/8828

(57) ABSTRACT

A switch including: first, second, and third electrodes; a region of phase-change material coupling the first, second, and third electrodes; and first, second, and third heater elements connected between a first surface of the region of phase-change material and the first, second, and third electrodes, respectively, the second and third heater elements being intended to modify the state of the phase-change material in first and second areas within said region.

### TECHNICAL FIELD

The present disclosure generally concerns electronic devices. The present disclosure more particularly concerns switches based on a phase-change material, capable of alternating between a crystalline, electrically-conductive, phase and an amorphous, electrically-insulating, phase.

### PRIOR ART

Various applications take advantage of switches based on a phase-change material to allow or prevent the flowing of an electric current in a circuit. Such switches may in particular be implemented in radio frequency communication applications, for example to switch an antenna between transmit and receive modes, to activate a filter corresponding to a frequency band, etc.

Existing switches based on a phase-change material however suffer from various disadvantages.

### SUMMARY OF THE INVENTION

There exists a need to improve existing switches based on a phase-change material.

For this purpose, an embodiment provides a switch comprising:
first, second, and third electrodes;
a region made of a phase-change material coupling the first, second, and third electrodes; and
first, second, and third heater elements connected between a first surface of the region of phase-change material and the first, second, and third electrodes, respectively, the second and third heater elements being intended to modify the state of the phase-change material in first and second areas within said region.

According to an embodiment, the first heater element is intended to modify the state of the phase-change material in a third area, different from the first and second areas, within the region of phase-change material.

According to an embodiment, the switch further comprises a fourth electrode and a fourth heater element connected between the first surface of the region of phase-change material and the fourth electrode, the fourth heater element being intended to modify the state of the phase-change material in a fourth area, different from the first and second zones, within said region.

According to an embodiment, the first, second, and third electrodes are respectively connected to first, second, and third conductive regions, each corresponding to a conduction electrode of a MOS transistor formed in a substrate.

According to an embodiment, the first, second, and third electrodes are respectively connected to first, second, and third control circuits, each comprising a node of application of a control potential.

According to an embodiment, the first and second areas interpenetrate.

According to an embodiment, the first and second areas are separate.

According to an embodiment, the first and second electrodes are intended to be connected to a radio frequency communication circuit and the third electrode is intended to be taken to a reference potential.

According to an embodiment, the switch further comprises at least one additional third heater element connected between the first surface of the region of phase-change material and the third electrode, each additional third heater element being intended to modify the state of the phase-change material in an additional second area within said region.

According to an embodiment, the switch further comprises at least one additional second heater element connected between the first surface of the region of phase-change material and the second electrode, each additional second heater element being intended to modify the state of the phase-change material in an additional first area within said region.

According to an embodiment, a second surface of the region of phase-change material, opposite to the first surface, is coated with a conductive layer.

According to an embodiment, the region of phase-change material is made of a chalcogenide material.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, and FIG. 1C are simplified and partial views, respectively a top view and a cross-section view along planes BB and CC of FIG. 1A, of an example of a switch based on a phase-change material according to an embodiment;

FIG. 2A, FIG. 2B, and FIG. 2C are simplified and partial top views illustrating different states of the switch of FIGS. 1A to 1C;

FIG. 3A, FIG. 3B, and FIG. 3C schematically and partially illustrate differences in operation between an example of a phase-change memory and the switch of FIGS. 1A to 1C;

FIG. 4A and FIG. 4C are simplified and partial views, respectively a top view and a cross-section view along plane CC of FIG. 4A, of an example of a switch based on a phase-change material according to an embodiment;

FIG. 5A and FIG. 5B are simplified and partial views, respectively a top view and a cross-section along plane BB of FIG. 5A, of an example of a switch based on a phase-change material according to an embodiment;

FIG. 6 is a simplified and partial top view of an example of a switch based on a phase-change material according to an embodiment;

FIG. 7 is a simplified and partial top view of an example of a switch based on a phase-change material according to an embodiment; and

FIG. 8 is a simplified and partial top view of an example of a switch based on a phase-change material according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the circuits for controlling switches based on a phase-change material and the applications in which such switches can be provided have not been detailed, the described embodiments and variants being compatible with circuits for controlling switches based on a phase-change material and with usual applications implementing switches based on a phase-change material.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

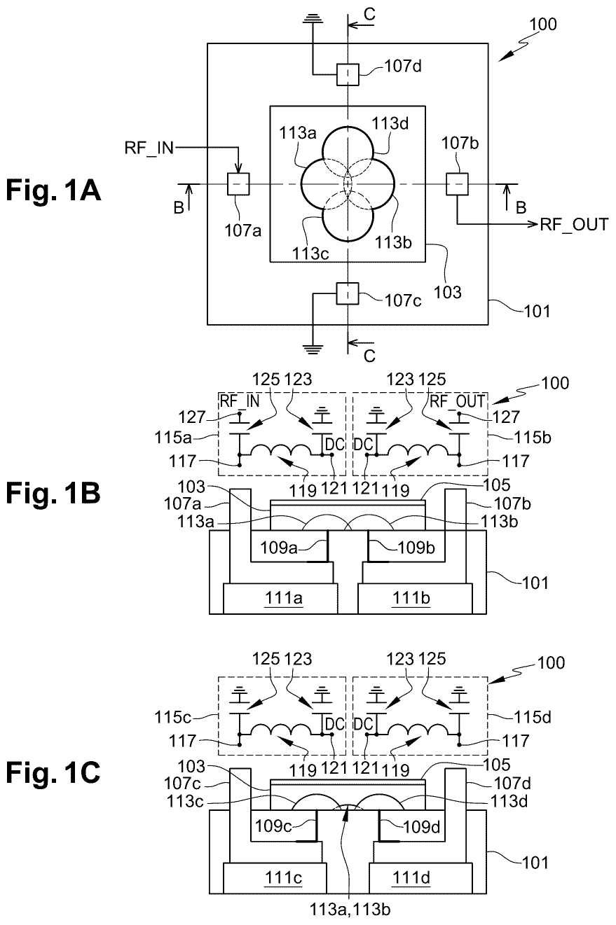

FIG. 1A is a simplified and partial top view of an example of a switch 100 based on a phase-change material according to an embodiment. FIG. 1B and FIG. 1C are cross-section views of switch 100 along planes BB and CC, respectively, of FIG. 1A.

In the shown example, switch 100 comprises a substrate 101. Substrate 101 is, for example, a wafer or piece of wafer made of a semiconductor material, such as silicon. As an example, substrate 101 is of CMOS (Complementary Metal-Oxide-Semiconductor) type and comprises a plurality of MOS (Metal-Oxide-Semiconductor) transistors, not detailed in FIGS. 1A to 1C so as not to overload the drawing.

In the illustrated example, a region 103 made of a phase-change material laterally extends on top of and in contact with a surface of substrate 101 (the upper surface of substrate 101, in the orientation of FIGS. 1B and 1C). Region 103 for example has, in top view, a periphery of rectangular or, as in the shown example, substantially square, shape. This example is however not limiting, and region 103 may, as a variant, have any shape.

As an example, region 103 of switch 100 is made of a material called “chalcogenide”, that is, a material or an alloy comprising at least one chalcogen element, for example, a material from the family of germanium telluride (GeTe), antimony telluride (SbTe), germanium-antimony-telluride (GeSbTe), more commonly designated by the acronym “GST”, or nitrogen-doped germanium telluride (GeTeN). Region 103 is for example made of GeTe, of SbTe, of GeSbTe, or of GeTeN. Region 103 is for example formed of a continuous layer of phase-change material.

In the shown example, the surface of the region of phase-change material 103 opposite to substrate 101 (the upper surface of region 103, in the orientation of FIGS. 1B and 1C) is coated with an electrically-conductive layer 105. Conductive layer 105 is for example deposited on the upper surface of region 103 of phase-change material. In the shown example, conductive layer 105 is continuous and fully coats the surface of region 103 opposite to substrate 101. Conductive layer 105 for example forms an upper electrode of switch 100, and is for example intended to be taken to a reference potential, for example, the ground. Layer 105 is, for example, based on a metal or on a metal alloy. As an example, layer 105 is made of titanium nitride (TiN). Layer 105 for example has a thickness in the range from 25 to 100 nm, for example in the order of 50 nm. Layer 105 has not been shown in FIG. 1A so as not to overload the drawing. As a variant, layer 105 may be omitted.

In the illustrated example, switch 100 further comprises electrodes 107, more precisely four electrodes 107a, 107b, 107c, and 107d, in this example. The electrodes 107 of switch 100 are insulated from each other. In the shown example, each electrode 107 has, in side view, an L shape with a horizontal portion laterally extending in substrate 101 vertically in line with layer 103, the horizontal portion of each electrode 107 being separated from layer 103 by a non-zero distance, and with a vertical portion vertically extending across the thickness of substrate 101 from an area of the upper surface of substrate 101 which is not coated with region 103. The vertical portion of each electrode 107 may, as in the illustrated example, project from the upper surface of substrate 101. This example is however not limiting, and the electrodes 107 may as a variant be flush with the upper surface of substrate 101.

The electrodes 107 of switch 100 are for example made of a conductive material, for example a metal or a metal alloy. For example, electrodes 107 are made of copper. To simplify the construction of switch 100, electrodes 107 have substantially identical structures and compositions, to within manufacturing dispersions.

Electrodes 107a and 107b are for example intended to be connected to a radio frequency communication circuit, and electrodes 107c and 107d are intended to be taken to a reference potential, for example, the ground. As an example, electrodes 107c and 107d may be interconnected. In the shown example, electrode 107a is an input electrode of switch 100 having a radio frequency signal RF_IN applied thereto, electrode 107b is an output electrode of switch 100 transmitting a radio frequency signal RF_OUT, and electrodes 107c and 107d are connected to ground.

In the shown example, switch 100 further comprises heater elements 109, specifically four heater elements 109a, 109b, 109c, and 109d. The heater elements 109 of switch 100 are insulated from one another. Heater elements 109a, 109b, 109c, and 109d are connected between the surface of region 103 coating substrate 101 (the lower surface of region 103, in the orientation of FIGS. 1B and 1C) and electrodes 107a, 107b, 107c, and 107d, respectively. In the illustrated example, each heater element 109a, 109b, 109c, 109d has an L shape, with a horizontal portion laterally extending on top of and in contact with the horizontal portion of the L formed by the corresponding electrode 107a, 107b, 107c, 107d, and with a vertical portion, located vertically in line with region 103 of phase-change material, vertically extending across the thickness of substrate 101 from the upper surface of substrate 101 to the corresponding electrode 107a, 107b, 107c, 107d. In the orientation of FIGS. 1B and 1C, the upper end of the vertical portion of each heater element 109 is flush with an area of the upper surface of substrate 101 coated with region 103 and is in mechanical contact with the lower surface of region 103. Heater elements 109 contact region 103 in different points, for example spaced apart from one another by a few tens of nanometers. FIGS. 1A to 1C illustrate an example where switch 100 comprises a single continuous conductive layer 105. However, this example is not limiting and switch 100 may, as a variant, comprise a plurality of separate conductive layers, for example four separate conductive layers respectively located vertically in line with areas of contact of heater elements 109 with the lower surface of region 103.

In the illustrated example, switch 100 further comprises conductive regions 111, more precisely four regions 111a, 111b, 111c and 111d, in the shown example. The conductive regions 111 of switch 100 are, for example, insulated from one another other, and correspond, for example, to conduction electrodes (source or drain) of MOS transistors formed in substrate 101. In the orientation of FIGS. 1B and 1C, each conductive region 111a, 111b, 111c, 111d is in mechanical contact, by its upper surface, with the lower surface of the horizontal portion of the L formed by electrode 107a, 107b, 107c, 107d, respectively.

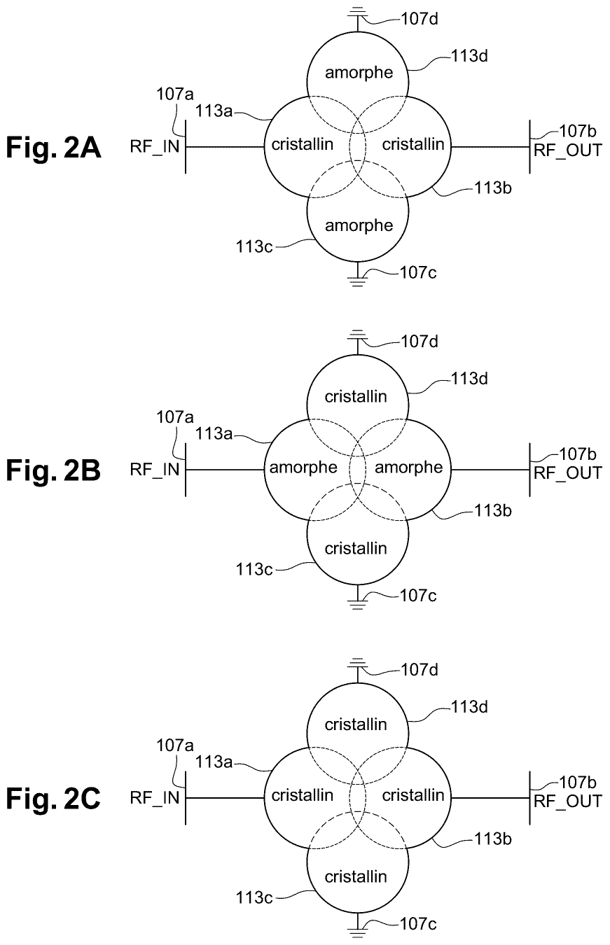

FIG. 2A, FIG. 2B, and FIG. 2C are simplified and partial top views illustrating different states of the switch of FIGS. 1A to 1C.

Phase-change materials are generally materials capable of alternating, under the effect of a temperature variation, between a crystalline phase and an amorphous phase, the amorphous phase having an electrical resistance higher than that of the crystalline phase. In the case of switch 100, advantage is taken of this phenomenon to obtain:
a first state (FIG. 2A), called “conducting state”, allowing the transmission of a radio frequency signal between electrodes 107a and 107b, when the material of two areas 113a and 113b of region 103, respectively located vertically in line with the vertical portions of heater elements 109a and 109b, is in the crystalline phase and when at least a portion of the material of two other areas 113c and 113d of region 103, respectively located vertically in line with the vertical portions of heater elements 109c and 109d, is in the amorphous phase;
a second state (FIG. 2B), called “reflective non-conducting state”, preventing the transmission of a radio frequency signal between electrodes 107a and 107b, when at least a portion of the material of areas 113a and 113b of region 103 is in the amorphous phase and when the material of areas 113c and 113d of region 103 is in the crystalline phase; and
a third state (FIG. 2C), called “absorbing non-conducting state”, allowing a partial transmission of a radio frequency signal between electrodes 107a and 107b, and possibly between electrode 107a and electrodes 107c and 107d, when the material of areas 113a, 113b, 113c, and 113d of region 103 is in the crystalline phase.

In the shown example, each area 113a, 113b, 113c, 113d of region 103 has the shape of a spherical cap substantially centered, in top view, with respect to the location where the vertical portion of the heater element 109a, 109b, 109c, 109d, intended to modify the state of the phase-change material in the corresponding zone, is in mechanical contact with the lower surface of region 103. In the illustrated example, areas 113a, 113b, 113c, and 113d interpenetrate, each area 113a, 113b, 113c, 113d being in contact with all the other areas. As an example, each area 113a, 113b, 113c, 113d has, in top view, a maximum lateral dimension (corresponding, in this example, to the diameter of the base circle of the spherical cap formed by the considered area 113a, 113b, 113c, 113d) in the order of a few tens of nanometers, for example equal to approximately 40 nm.

During the switching of switch 100 between the conducting and reflective non-conducting states, control voltages are for example simultaneously applied between regions 111a, 111b, 111c, and 111d, on the one hand, and layer 105, on the other hand, to cause the flowing of a current through heater elements 109a, 109b, 109c, and 109d, respectively. This current causes, by Joule effect and then by radiation and/or conduction within the structure of switch 100, in particular through layer 103, a temperature rise in areas 113a, 113b, 113c, and 113d from the lower surface of region 103.

More precisely, to have switch 100 switch from the reflective non-conducting state to the conducting state, areas 113a and 113b of region 103 of phase-change material are heated, by means of heater elements 109a and 109b, for example to a temperature T1 and for a time period d1. Temperature T1 and time period d1 are selected so as to cause a phase change of the material of areas 113a and 113b from the amorphous phase to the crystalline phase. Temperature T1 is, for example, higher than a crystallization temperature and lower than a melting temperature of the material of region 103. As an example, temperature T1 is in the range from 150 to 350° C. and time period d1 is shorter than 1 μs. In the case where region 103 is made of germanium telluride, temperature T1 is, for example, equal to approximately 300° C. and time period d1 is, for example, in the range from 100 ns to 1 μs.

Further, areas 113c and 113d of region 103 of phase-change material are heated, by means of heater elements 109c and 109d, for example to a temperature T2 higher than temperature T1, and for a time period d2 shorter than time period d1. Temperature T2 and time period d2 are selected so as to cause a phase change of the material of areas 113c and 113d from the crystalline phase to the amorphous phase. Temperature T2 is, for example, higher than the melting temperature of the phase-change material. As an example, temperature T2 is in the range from 600 and 1,000° C. and time period d2 is shorter than 500 ns. In the case where region 103 is made of germanium telluride, temperature T2 is, for example, equal to approximately 700° C. and time period d2 is, for example, equal to approximately 100 ns.

During the switching of switch 100 between the reflective non-conducting state and the conducting state, heater elements 109a, 109b, 109c, and 109d are for example simultaneously controlled. This advantageously enables to decrease the switching time.

Conversely, to have switch 100 switch from the conducting state to the reflective non-conducting state, areas 113a and 113b are heated, by means of heater elements 109a and 109b, for example to temperature T2 and for time period d2. Further, areas 113c and 113d are heated, by means of heater elements 109c and 109d, for example to temperature T1 and for time period d1.

Thus, during the switching between the conductive state and the reflective non-conducting state, heater elements 109a and 109b, on the one hand, and heater elements 109c and 109d, on the other, are controlled simultaneously and in opposition. As an example, heater elements 109c and 109d are intended to be controlled so as to have areas 113c and 113d of phase-change material change from a first state to a second state (for example, from the crystalline state to the amorphous state) when heater elements 109a and 109b are controlled so as to have areas 113a and 113b of phase-change material change from the second to the first state (from the amorphous state to the crystalline state, in this example).

The switching between the reflective non-conducting and absorbing non-conducting states is, for example, similar to the switching between the conducting and reflective non-conducting states described hereabove, with the difference that only heater elements 109a and 109b are implemented for the switching between the reflective non-conducting and absorbing non-conducting states, the material in areas 113c and 113d remaining in the crystalline phase during this switching. For example, to have switch 100 switch from the reflective non-conducting state to the absorbing non-conducting state, areas 113a and 113b of region 103 are heated to temperature T1 and for time period d1. Conversely, to have switch 100 switch from the absorbing non-conducting state to the reflecting non-conducting state, areas 113a and 113b are heated, for example, to temperature T2 and for time period d2.

Further, the switching between the conducting and absorbing non-conducting states is, for example, similar to the switching between the conductive and reflective non-conducting states described hereabove, with the difference that only heater elements 109c and 109d are implemented for the switching between the conducting and absorbing non-conducting states, the material of areas 113a and 113b remaining in the crystalline phase during this switching. As an example, to have switch 100 switch from the conducting state to the absorbing non-conducting state, areas 113c and 113d of region 103 are heated to temperature T1 and for time period d1. Conversely, to have switch 100 switch from the absorbing non-conducting state to the conducting state, areas 113c and 113d are heated, for example, to temperature T2 and for time period d2.

The values of temperatures T1 and T2 and of heating time periods d1 and d2 may be substantially identical for each of areas 113a, 113b, 113c, 113d.

As a variant or additionally, the heater elements 109a, 109b, 109c, and 109d of switch 100 may be controlled by control circuits 115, more precisely by four control circuits 115a, 115b, 115c, and 115d, respectively, in this example. Each circuit 115a, 115b, 115c, 115d comprises:
a node 117 intended to be connected to the corresponding electrode 107a, 107b, 107c, 107d;
an inductive element 119 connected between node 117 and another node 121 of application of a control potential, for example, a DC potential;
a capacitive element 123 connected between node 121 and another node of application of a reference potential, for example, the ground; and
another capacitive element 125 connected between node 117 and, in the case of circuits 115a and 115b, another node 127 of application of a radio frequency signal corresponding, for example, to signal RF_IN for circuit 115a and to signal RF_OUT for circuit 115b or, in the case of circuits 115c and 115d, another node of application of a reference potential, for example the ground.

As an example, circuits 115a, 115b, 115c, and 115d may be formed in substrate 101 or in another substrate stacked on substrate 101, in the orientation of FIGS. 1B and 1C.

During the switching of switch 100 between the conducting, reflective non-conducting, and absorbing non-conducting states, control circuits 115a, 115b, 115c, and 115d may, together with regions 111 or instead of regions 111, be implemented to apply to heater elements 109a, 109b, 109c, and 109d the adequate voltage enabling the corresponding areas 113a, 113b, 113c, and 113d to alternate between amorphous and crystalline phases as previously discussed. In other words, the bias voltage of each heater element 109 of switch 100 may be applied either by means of regions 111 alone, or by means of circuits 115 alone, or jointly by means of regions 111 and of circuits 115.

Switch 100 advantageously uses the operating principle of a memory of PCRAM (Phase-Change Random Access Memory) type but with four memory areas, in the shown example, unlike a PCRAM cell which uses a single one. Switch 100 also differs from existing radio frequency switches based on phase-change material in that it does not require switching the entire volume of phase-change material of region 103. In switch 100, the four memory areas are obtained due to the presence of five terminals, in the case in point heater elements 109 and conductive region 105, arranged to change the phase of the material in areas 113. The presence of these four memory areas enables the structure to meet the requirements of a radio frequency switch, particularly in terms of ratio R_{off}/Rₒₙ, unlike existing PCRAM memory cells which have lower ratios R_{off}/Rₒₙ. As an example, the ratio R_{off}/Rₒₙ of switch 100 is greater than one thousand, or even greater than ten thousand, while a PCRAM memory cell has a ratio R_{off}/Rₒₙ ratio in the order of one hundred.

An advantage of switch 100 lies in the fact that the reflective non-conducting state enables to obtain a better insulation, for example, improved by approximately −20 dB, between electrodes 107a and 107b than in the case of similar switch but without, for example, electrodes 107c and 107d, heater elements 109c and 109d, and regions 111c and 111d. Another advantage of switch 100 lies in the fact that it is possible to take advantage of the absorbing non-conducting state to attenuate the signal transmitted between conduction electrodes 107a and 107b.

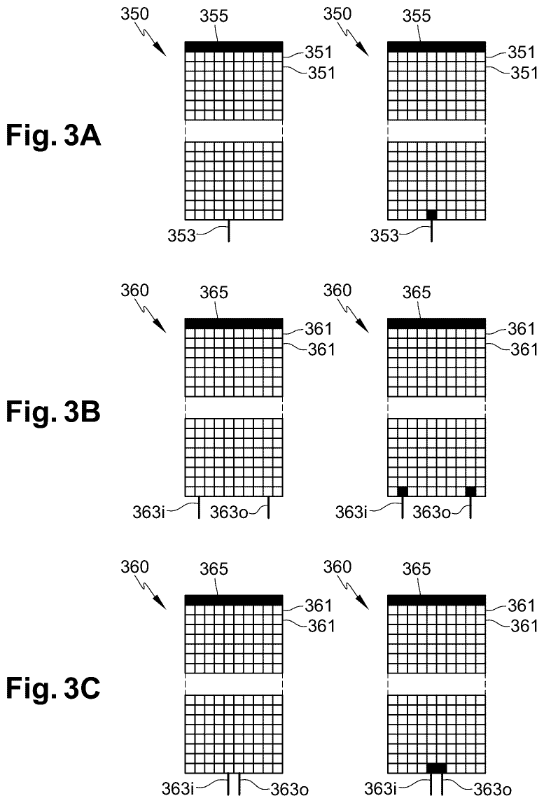

FIG. 3A, FIG. 3B, and FIG. 3C illustrate, schematically and partially, differences in operation between an example of a phase-change memory and the switch of FIGS. 1A to 1C.

FIG. 3A schematically shows an area 350 made of a phase-change material, broken down into columns, each comprising one hundred square unit cells 351. In the left-hand portion of FIG. 3A, the material of the unit cells 351 of each column is in the crystalline state. As an example, each unit cell 351 has a unit resistance substantially equal to 1Ω, in the crystalline state, and substantially equal to 1 kΩ, in the amorphous state. On the left-hand side, in the illustrated example, area 350 has an on-state resistance Rₒₙ substantially equal to 100Ω (one hundred 1-Ω unit cells in series). Resistance Rₒₙ corresponds, for example, to an on-state resistance between a lower input pin 353 and an upper electrode 355. In the right-hand portion of FIG. 3A, the unit cell 351 in contact with pin 353 switches from the crystalline state to the amorphous state. Area 350 then has an off-state resistance R_{off} substantially equal to 10,099Ω (99 unit cells of 1Ω and one unit cell of 10 kΩ in series). Resistance R_{off} corresponds to an off-state resistance between pin 353 and electrode 355. In the configuration illustrated in FIG. 3A, ratio R_{off}/Rₒₙ is substantially equal to one hundred (10,099/100). This configuration typically corresponds to a PCRAM memory comprising a lower electrode (lower pin 353) and an upper electrode 355. Such a ratio R_{off}/Rₒₙ is not compatible with a radio frequency switch application.

FIG. 3B schematically shows an area 360 of phase-change material broken down into columns, each comprising one hundred square unit cells 361. In the left-hand portion of FIG. 3B, the material of the unit cells 361 of each column is in the crystalline state. As an example, each unit cell 361 has an elementary resistance substantially equal to 1Ω, in the crystalline state, and substantially equal to 1 kΩ, in the amorphous state. On the left-hand side, in the shown example, area 360 has, between a lower input pin 353i and a lower output pin 353o, an on-state resistance Rₒₙ substantially equal to 7Ω (two half-squares of 0.5Ω and six full squares of 1Ω in series between pins 353i and 353o). On the right-hand side of FIG. 3B, the unit cells 361 respectively in contact with pins 363i and 363o switch from the crystalline state to the amorphous state. Area 360 then has, between pins 363i and 363o, an off-state resistance R_{off} substantially equal to 10,006Ω (two half-squares of 5 kΩ and six full squares of 1Ω in series between pins 353i and 353o). In the configuration illustrated in FIG. 3B, ratio R_{off}/Rₒₙ is substantially equal to 1,429 (10,006/7). As compared with the configuration of FIG. 3A, the configuration of FIG. 3B advantageously increases ratio R_{off}/Rₒₙ by a factor greater than 10. The switching of the elementary areas 361 in contact with pins 363i and 363o is performed, for example, by respectively applying a first control signal between input pin 363i and an upper electrode 365, and a second control signal, different from the first control signal, between output pin 363o and the electrode 365. Input pin 363i and output pin 363o are for example similar or identical to two of the heater elements 109 of switch 100, for example heater elements 109b and 109d, and upper electrode 365 is for example similar or identical to the conductive layer 105 of switch 100.

Ratio R_{off}/Rₒₙ may be further increased by bringing the input pin 363i and the output pin 363o towards each other, as shown in FIG. 3C. In this case, resistance Rₒₙ is equal to approximately 1Ω (two 1-Ω half-squares in series between pins 353i and 353o) and resistance R_{off} is equal to approximately 10 kΩ (two 5-kΩ half-squares in series). In this case, ratio R_{off}/Rₒₙ is equal to approximately 10,000. As compared with the configuration of FIG. 3A, the configuration of FIG. 3C enables to increase the ratio R_{off}/Rₒₙ by a factor in the order of a hundred.

Switch 100 takes advantage of a PCRAM-type structure comprising at least two lower electrodes enabling to create two memory areas by means of a third upper electrode, this configuration enabling to keep the advantages of a PCRAM memory in terms of switching time while gaining a factor of ten, one hundred, or more on ratio R_{off}/Rₒₙ.

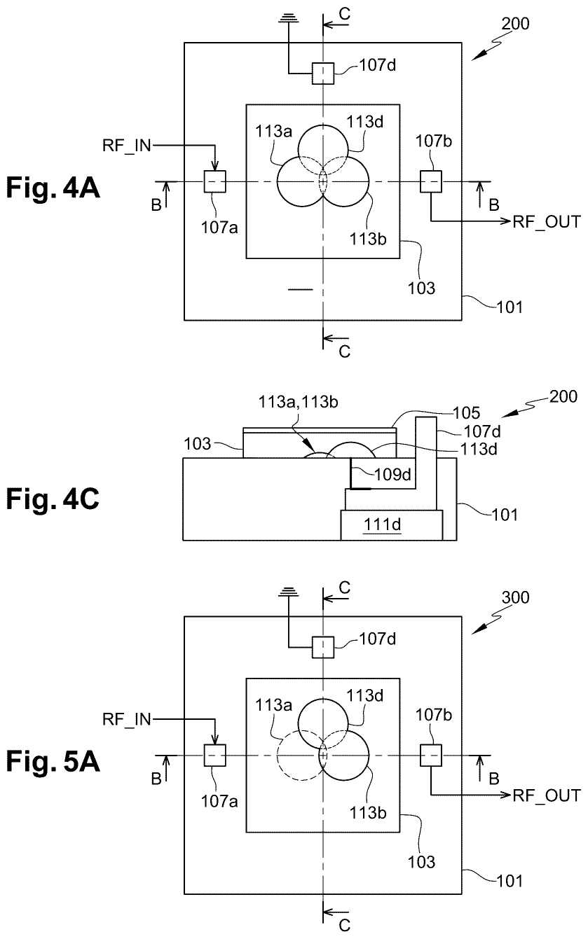

FIG. 4A is a simplified and partial top view of an example of a switch 200 based on a phase-change material according to an embodiment. FIG. 4C is a cross-section view, along plane CC of FIG. 4A, of switch 200. Switch 200 has, in cross-section view along plane BB in FIG. 4A, a structure similar or identical to that of the switch 100 illustrated in FIG. 1B.

The switch 200 of FIGS. 4A and 4C comprises elements in common with the switch 100 of FIGS. 1A to 1C. These common elements will not be detailed again hereafter. The switch 200 of FIGS. 4A and 4C differs from the switch 100 of FIGS. 1A to 1C in that switch 200 does not comprise electrode 107c, heater element 109c, and conductive region 111c. The operation of switch 200 is, for example, similar to that of the switch 100 previously discussed in relation with FIGS. 1A to 1C. The operation of switch 200 differs from that of switch 100 in that, in switch 200, only heater elements 109a, 109b, and 109d are controlled to enable to obtain the conducting, reflective non-conducting, and absorbing non-conducting states.

Although this has not been illustrated in FIG. 4C, the electrode 107d of switch 200 may be connected to the control circuit 115d previously described in relation with FIG. 1C.

An advantage of switch 200 is that it has a structure comprising fewer components than switch 100. This enables to simplify the design and the control of switch 200 as compared with switch 100.

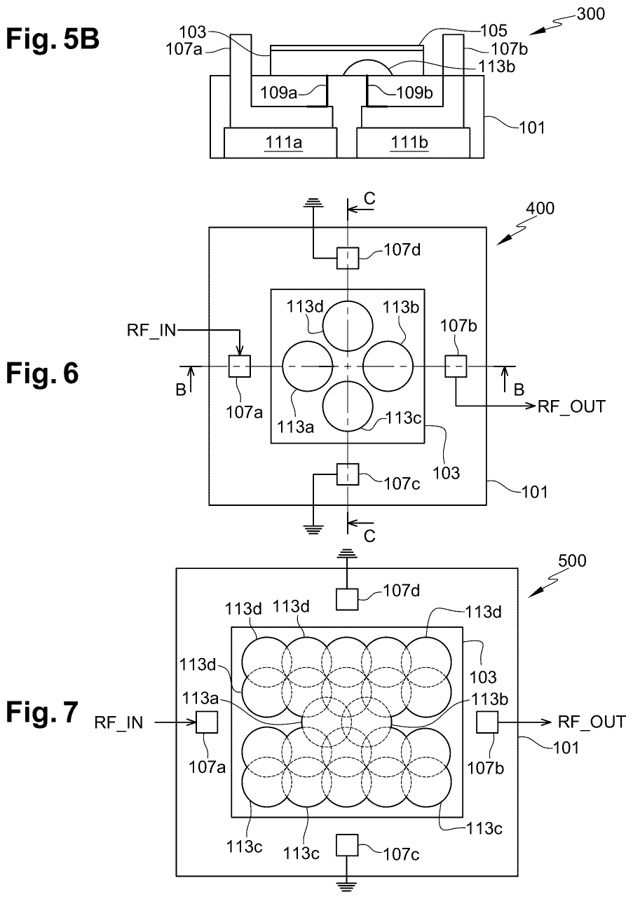

FIG. 5A is a simplified and partial top view of an example of a switch 300 based on a phase-change material according to an embodiment. FIG. 5B is a cross-section view, along plane BB of FIG. 5A, of switch 300. Switch 300 has, in cross-section along plane CC of FIG. 5A, a structure similar or identical to that of the switch 200 illustrated in FIG. 4C.

The switch 300 of FIGS. 5A and 5B comprises elements in common with the switch 200 of FIGS. 4A and 4C. These common elements will not be detailed again hereafter. The switch 300 of FIGS. 5A and 5B differs from the switch 200 of FIGS. 4A and 4C in that the heater element 109a of switch 300 is not intended to modify the state of the phase-change material in area 113a of region 103, the material remaining, for example, in the crystalline phase within this area whatever the state of switch 300. As an example, control circuit 115a and/or conductive region 111a may be omitted.

The operation of switch 300 is, for example, similar to that of the switch 100 described hereabove in relation with FIGS. 1A to 1C. The operation of switch 300 differs from that of switch 100 in that, in switch 300, heater element 109a is submitted to no control potential intended to modify the phase of area 113a. Although this has not been illustrated in FIG. 5B, electrode 107b of switch 300 may be connected to the control circuit 115b previously described in relation with FIG. 1B.

An advantage of switch 300 lies in the fact that it has a structure comprising fewer elements than switch 100. This enables to simplify the design and the control of switch 300 as compared with switch 100.

FIG. 6 is a simplified and partial top view of an example of a switch 400 based on a phase-change material according to an embodiment. Switch 400 has, in cross-section along planes BB and CC of FIG. 6, a structure similar to that of the switch 100 illustrated in FIGS. 1B and 1C, respectively.

The switch 400 of FIG. 6 comprises elements in common with the switch 100 of FIGS. 1A to 1C. These common elements will not be detailed again hereafter. The switch 400 of FIG. 6 differs from the switch 100 of FIGS. 1A to 1C in that the areas 113a, 113b, 113c, and 113d of switch 400 are separate. In the shown example, each area 113a, 113b, 113c, 113d is separated from the other areas by portions of region 103 which remain in the crystalline phase whatever the state of switch 400, region 103 being, for example, in the crystalline phase once switch 400 has been manufactured. Switch 400 corresponds, for example, to a case where heater elements 109 are further apart than in the case of switch 100, for example due to manufacturing dispersions.

Although FIG. 6 illustrates an example where all areas 113a, 113b, 113c, and 113d are separate, switch 400 may as a variant comprise at least two adjacent, or interpenetrating, areas 113a, 113b, 113c, and 113d.

The operation of switch 400 is, for example, identical to that of the switch 100 described hereabove in relation with FIGS. 1A to 1C.

FIG. 7 is a simplified and partial top view of an example of a switch 500 based on a phase-change material according to an embodiment.

The switch 500 of FIG. 7 comprises elements in common with the switch 100 of FIGS. 1A to 1C. These common elements will not be detailed again hereafter. The switch 500 of FIG. 7 differs from the switch 100 of FIGS. 1A to 1C in that switch 500 comprises a plurality of heater elements 109c connected to electrode 107c, and a plurality of heater elements 109d connected to electrode 107d. Heater elements 109c and 109d have not been shown in FIG. 7 so as not to overload the drawing. The heater elements 109c and 109d of switch 500 are capable of forming, in the region 103 of phase-change material, a plurality of adjacent areas 113c and a plurality of adjacent areas 113d, each area 113c, 113d being substantially centered on the location where heater element 109c, 109d is in mechanical contact with region 103. Heater elements 109c and 109d are, for example, connected to region 103, on the one hand, and to electrode 107c or 107d, on the other hand. The operation of switch 500 is, for example, identical to that of the switch 100 described hereabove in relation with FIGS. 1A to 1C. The switching of areas 113c and 113d of switch 500 between crystalline and amorphous phases is for example controlled simultaneously.

FIG. 7 illustrates an example where switch 500 comprises two rows of areas 113c and two rows of areas 113d, for example each associated with a row of heater elements 109c or 109d. This example is however not limiting, and switch 500 may comprise any number, greater than or equal to one, for example between one and five, of rows of areas 113c and of rows of areas 113d. Areas 113c and 113d may, as a variant, be organized differently than in the form of rows. Further, although FIG. 7 illustrates an example where the rows comprise identical numbers of areas 113c or 113d, this example is not limiting, and switch 500 may, as a variant, have any number, greater than or equal to one, of areas 113c or 113d per row. In other words, switch 500 may comprise any number, greater than or equal to one, of heater elements 109c and any number, greater than or equal to one, of heater elements 109d, which heater elements may be organized in the form of any number of rows, each comprising any number, greater than or equal to one, of heater elements.

An advantage of switch 500 lies in the fact that the placing in parallel of areas 113c and 113d enables to decrease the series resistance of ground connections and to increase the insulation when the switch is in the reflective non-conducting state.

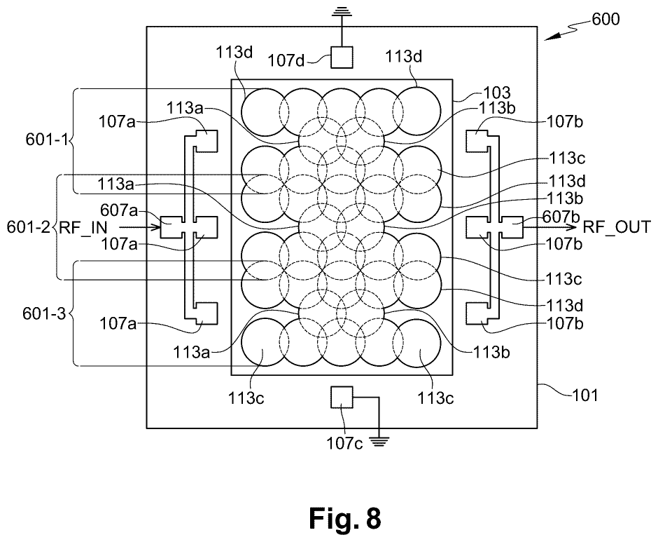

FIG. 8 is a simplified and partial top view of an example of a switch 600 based on a phase-change material according to an embodiment.

The switch 600 of FIG. 8 has elements in common with the switch 500 of FIG. 7. These common elements will not be detailed again hereafter. The switch 600 of FIG. 8 differs from the switch 500 of FIG. 7 in that switch 600 comprises a plurality of heater elements 109a and a plurality of heater elements 109b. Heater elements 109a and 109b have not been shown in FIG. 8 so as not to overload the drawing. The heater elements 109a and 109b of switch 600 are capable of forming, in region 103 of phase-change material, a plurality of pairs of adjacent areas 113a 113b, each area 113a, 113b being substantially centered on the location where heater element 109a, 109b is in mechanical contact with region 103.

In the shown example, the heater elements 109a, 109b, 109c, and 109d of switch 600 are capable of forming a plurality of assemblies 601, each comprising areas 113a and 113b laterally interposed between a row of areas 113c and a row of areas 113d. More specifically, in the illustrated example, switch 600 comprises three assemblies 601-1, 601-2 and 601-3 laterally interposed between electrodes 107c and 107d. In the shown example, the areas 113c of assembly 601-1 and the adjacent areas 113d of assembly 601-2 interpenetrate, and the areas 113c of assembly 601-2 and the adjacent areas 113d of assembly 601-3 interpenetrate.

In the example illustrated in FIG. 8, the electrodes 107a of assemblies 601-1, 601-2, and 601-3 are connected to a same electrode 607a, and the electrodes 107b of assemblies 601-1, 601-2, and 601-3 are connected to a same electrode 607b. Further, although this has not been detailed in FIG. 8, the areas 113c of assemblies 601-1, 601-2, and 601-3 are for example connected to electrode 107c, and the areas 113d of assemblies 601-1, 601-2, and 601-3 are for example connected to electrode 107d.

Although FIG. 8 illustrates an example where switch 600 comprises three assemblies 601, each comprising a row of areas 113c and a row of areas 113d, switch 600 may as a variant comprise any number, greater than or equal to one, of assemblies 601, and each assembly 601 may further comprise any number, greater than or equal to zero, of rows of areas 113c and rows of areas 113d. Each row of areas 113c and each row of areas 113d may further comprise any number, greater than or equal to zero, of areas 113c and 113d, respectively. In other words, switch 600 may comprise any number, greater than or equal to one, of heater elements 109a and any number, greater than or equal to one, of heater elements 109b, and switch 600 may further comprise any number of heater elements 109c and/or 109d.

Switch 600 has an operation and advantages similar or identical to those of switch 500. Switch 600 also has the advantage, due to the placing in parallel of a plurality of areas 113a and 113b, of decreasing the resistance between electrodes 607a and 607b. This decreases insertion losses when the switch is in the conducting state, that is, the on-state transmission is improved.

Various embodiments and variants have been described. Those skilled in the art will understand that certain features of these various embodiments and variants may be combined, and other variants will occur to those skilled in the art. In particular, those skilled in the art will be capable of combining:
the embodiment of switch 300 with that of switch 100, for example so as to obtain a structure similar to that of switch 100 but in which heater element 109a is not controlled so as to modify the phase of area 113a;
the embodiment of switch 400 with that of switch 200 or 300, for example so as to obtain a structure similar to that of switch 200 or 300, but in which at least one of areas 113a, 113b, 113c, and 113d is separate from at least one of the other areas adjacent to the considered area; the embodiment of switch 200 with that of switch 500 or 600, for example so as to obtain a structure similar to that of switch 500 or 600 but without electrode 107c and areas 113c; and
the embodiment of switch 300 with that of switch 500 or 600, for example so as to obtain a structure similar to that of switch 500 or 600 but in which heater element 109a is not controlled so as to modify the phase of area(s) 113a.

Finally, the practical implementation of the described embodiments and variants is within the abilities of those skilled in the art based on the functional indications given hereabove. In particular, those skilled in the art are capable of integrating the switches 100, 200, 300, 400, 500, and 600 described hereabove into various radio frequency devices such as a microstrip line, a coplanar waveguide (CPW), etc.

Further, the described embodiments are not limited to the specific examples of materials and dimensions mentioned in the present disclosure.

1. Switch comprising:
first, second and third electrodes;
a region made of a phase-change material coupling the first, second, and third electrodes; and
first, second, and third heater elements connected between a first surface of the region of phase-change material and the first, second, and third electrodes, respectively; and
a continuous conductive layer integrally coating a second surface of the region of phase-change material opposite to the first surface,
the second and third heater elements being intended to modify the state of the phase-change material in first and second areas within said region by application respectively of a first control signal between the conductive layer and the second heater element, and of a second control signal between the conductive layer and the third heater element,
wherein the first and second electrodes are intended to be connected to a radio frequency communication circuit and the third electrode is intended to be taken to a reference potential.

2. Switch according to claim 1, wherein the first heater element is intended to modify the state of the phase-change material in a third area, different from the first and second areas, within the region of phase-change material.

3. Switch according to claim 1, further comprising a fourth electrode and a fourth heater element connected between the first surface of the region of phase-change material and the fourth electrode, the fourth heater element being intended to modify the state of the phase-change material in a fourth area, different from the first and second areas, within said region.

4. Switch according to claim 3, wherein the third and fourth heater elements are intended to be controlled so as to have the third and fourth zones of phase-change material change from a first state to a second state when the first and second heater elements are controlled so as to have the first and second areas, of phase-change material change from the second to the first state.

5. Switch according to claim 1, wherein the first, second, and third electrodes are respectively connected to first, second, and third conductive regions, each corresponding to a conduction electrode of a MOS transistor formed in a substrate.

6. Switch according to claim 1, wherein the first, second, and third electrodes are respectively connected to first, second, and third control circuits, each comprising a node of application of a control potential.

7. Switch according to claim 1, wherein the first and second areas interpenetrate.

8. Switch according to claim 1, wherein the first and second areas are separate.

9. Switch according to claim 1, further comprising at least one additional third heater element connected between the first surface of the region of phase-change material and the third electrode, each additional third heater element being intended to modify the state of the phase-change material in an additional second area within said region.

10. Switch according to claim 1, further comprising at least one additional second heater element connected between the first surface of the region of phase-change material and the second electrode, each additional second heater element being intended to modify the state of the phase-change material in an additional first area within said region.

11. Switch according to claim 1, wherein the region of phase-change material is made of at least one chalcogenide material, preferably selected from among GeTe, GeSbTe, SbTe, and GeTeN.
